(19) United States
(12) Patent Application Publication
(10) Pub. No.: US 2008/0160716 A1
(43) Pub. Date: Jul. 3, 2008

(54) METHOD FOR FABRICATING AN ISOLATION LAYER IN A SEMICONDUCTOR DEVICE

(75) Inventors: Hye Jin Seo, Icheon-si (KR); Eun A. Lee, Seoul (KR); An Bae Lee, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/770,522

(22) Filed: Jun. 28, 2007

(30) Foreign Application Priority Data
Dec. 29, 2006 (KR) 10-2006-138831

(51) Int. Cl. H01L 21/762

(52) U.S. Cl. 438/425; 257/E21.546

(57) ABSTRACT

A method for forming an isolation layer in a semiconductor device includes forming a trench inside a semiconductor substrate, forming a fluid insulating layer over the semiconductor substrate, thereby filling the trench with the fluid insulating layer, curing the semiconductor substrate by plasma oxidation to densify the fluid insulating layer, and planarizing the fluid insulating layer to form an isolation layer.

### CROSS-REFERENCE TO RELATED APPLICATION

Priority to Korean patent application number 10-2006-138831, filed on Dec. 29, 2006, the disclosure of which is incorporated by reference in its entirety, is claimed.

### BACKGROUND OF THE INVENTION

The invention relates to a semiconductor device. More specifically, the invention relates to a method for forming an isolation layer in a semiconductor device capable of ensuring stability with an improvement in the curing process for the isolation layer.

In recent trends toward highly-integrated, fine-pattern semiconductor devices, there has been an increased demand for shallow trench isolation (STI) techniques exhibiting superior device isolation with a small width. The formation of an isolation layer with shallow trench isolation techniques generally includes forming a trench inside a semiconductor substrate, filling the trench with an insulating layer and planarizing the resulting structure.

To improve the ability to fill the trench, a high density plasma (HDP) oxide layer is used as a gap-fill material and a deposition-etching-deposition (DED) process is used as a gap-fill method. However, there is a limitation in applying such a gap-fill material and method to a trench having a low gap-fill margin due to the reduced size of the trench. Accordingly, a fluid insulating layer exhibiting superior step coverage has been used. The fluid insulating layer is capable of filling a narrow trench due to its high reflowability. The fluid insulating layer is densified by applying a coater and subsequent curing.

Steam annealing involving heat-treatment at 900° C. or higher is generally used as the curing method to densify the fluid insulating layer. Steam annealing induces excessive oxidation in an active region and prolongs the cleaning time required to remove the remaining oxide layer. As a result, defects (e.g., a moat) occur due to an increase in damage to the isolation layer. In addition, loss in the substrate of the active region may take place. Several defects (e.g. a bird's beak) in a gate insulating layer may occur. Furthermore, the curing influence cannot reach the inside of the fluid insulating layer, thus making it difficult to form a uniform isolation layer.

FIG. 1 is a cross-sectional view illustrating a conventional curing method.

Referring to FIG. 1, trenches are formed inside a semiconductor substrate 10 via a mask pattern 12. The trenches are divided into trenches 14 having a small width and trenches 16 having a large width based on a pattern formation region. Subsequently, a fluid insulating layer 18 is formed on the resulting structure such that it fills the trenches 14 and 16. In the upper region A of the fluid insulating layer 18 and the internal region C of the trenches 16 a subsequent curing step actively progresses. On the other hand, the curing influence hardly reaches the internal region B of the trenches 14. As a result, the difference between the upper and lower regions of the fluid insulating layer 18 result in different etching rates of the fluid insulating layer is, thus making it difficult to form a uniform isolation layer.

### BRIEF SUMMARY OF THE INVENTION

In an attempt to solve the problems of the prior art, the invention provides a method for forming an isolation layer in a semiconductor device capable of ensuring high production efficiency, superior device stability and uniform etching rate with an improvement in the curing process of the isolation layer.

In accordance with one aspect of the invention, there is provided a method for forming an isolation layer in a semiconductor device including; forming a trench in a semiconductor substrate; forming a fluid insulating layer over the semiconductor substrate, thereby filling the trench with the fluid insulating layer; curing the semiconductor substrate by plasma oxidation to densify the fluid insulating layer; and planarizing the fluid insulating layer to form an isolation layer.

The method may further preferably include: after the formation of the trench, forming a sidewall oxide layer over the exposed region of the trench; and forming a liner nitride layer over the sidewall oxide layer.

The fluid insulating layer preferably includes a spin-on dielectric (SOD) material or polysilazane.

The step of curing preferably includes: loading the semiconductor substrate into a curing system; introducing argon (Ar) gas into the curing system to generate plasma in the curing system; and densifying the fluid insulating layer by introducing an oxidation source into the curing system, the oxidation source comprising oxygen (O₂) gas, hydrogen (H₂) gas or mixtures thereof.

The plasma oxidation is preferably carried out at a temperature of 250° C. to 350° C. and a pressure of 0.1 Torr to 1 Torr.

The curing is preferably carried out in a furnace using a microwave of 2 GHz to 2.5 GHz.

Preferably the oxidation source includes hydrogen (H₂) gas and oxygen (O₂) gas, the hydrogen (H₂) gas being used in an amount of 40% or less relative to the amount of oxygen (O₂) gas.

The plasma generation is preferably carried out by remote plasma generation.

### BRIEF DESCRIPTION OF THE DRAWINGS

The above and other aspects, features, and advantages of the invention will be more clearly understood from the following detailed description taken in conjunction with the accompanying drawings, in which:

FIG. 1 is a cross-sectional view illustrating a conventional curing method;

FIGS. 2 to 7 are cross-sectional views illustrating a method for forming an isolation layer in a semiconductor device according to one embodiment of the invention; and

FIG. 8 is a graph illustrating the variation in etching rate as a function of time delay.

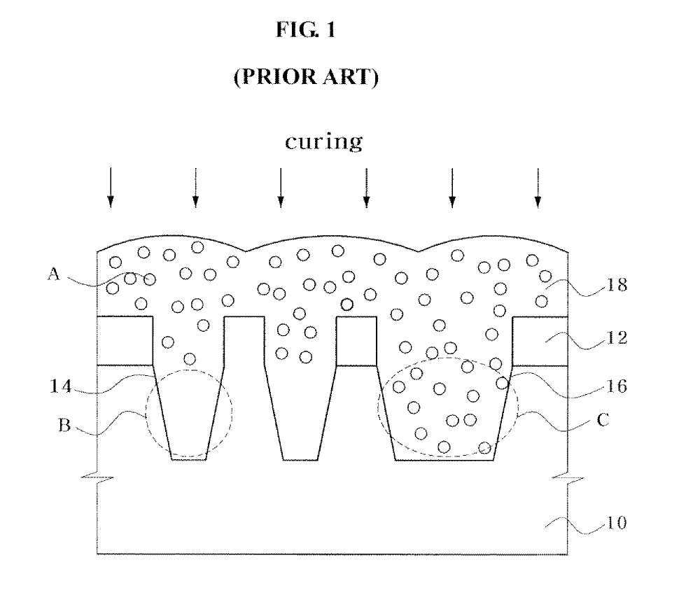

### DETAILED DESCRIPTION OF THE INVENTION

Exemplary embodiments of the invention are described in detail with reference to the accompanying drawings. In the drawings, the thickness of each element of is enlarged for clarity. Throughout the disclosure, the same or similar elements are denoted by the same reference numerals.

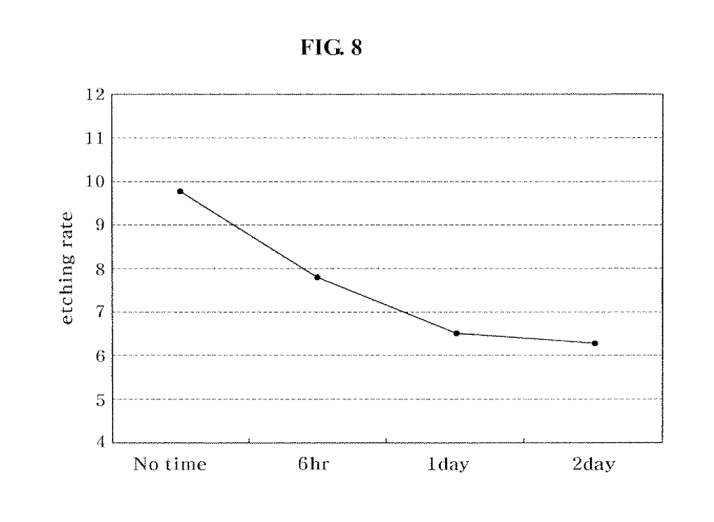

FIGS. 2 to 7 are cross-sectional views illustrating a method for forming an isolation layer in a semiconductor device according to one embodiment of the invention. FIG. 8 is a graph illustrating the variation in the etching rate as a function of time delay.

Referring to FIG. 2, a pad oxide layer 102 and a pad nitride layer 104 are sequentially deposited on a semiconductor substrate 100. Although not shown, since the pad oxide layer 102 and the pad nitride layer 104 are formed in a furnace, they are formed on the back of a wafer. The pad oxide layer 102 lessens the stress on the semiconductor substrate 100 caused by the attraction of the pad nitride layer 104. Then, a photosensitive layer (not shown) is applied to the surface of the pad nitride layer 104, followed by exposure to light and patterning, thereby forming a photosensitive layer pattern 106 through which the surface of the pad nitride layer 104 is partially exposed. The exposed region of the pad nitride layer 104 is where a trench will be subsequently formed.

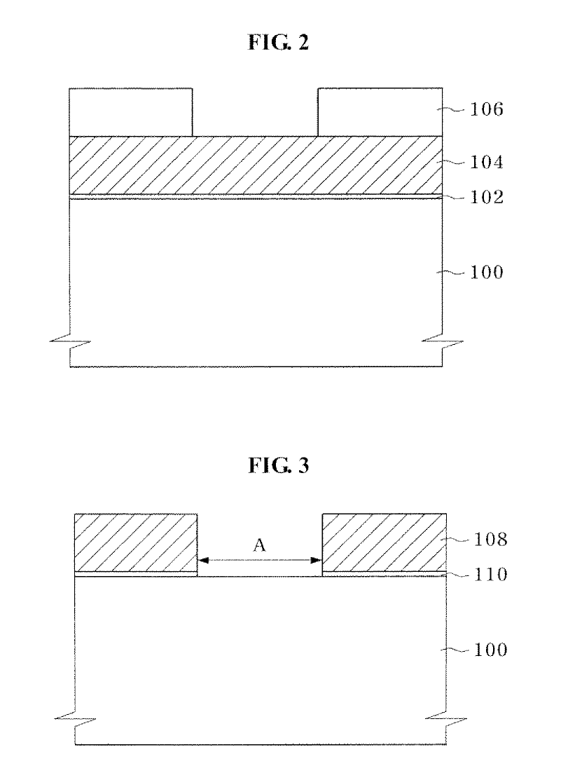

Referring to FIG. 3, the exposed regions of the pad nitride layer 104 and the pad oxide layer 102 are sequentially etched using the photosensitive layer pattern 106 as an etching mask, thereby forming a pad nitride layer pattern 108 and a pad oxide layer pattern 110 such that an isolation region A of the semiconductor substrate 100 is exposed.

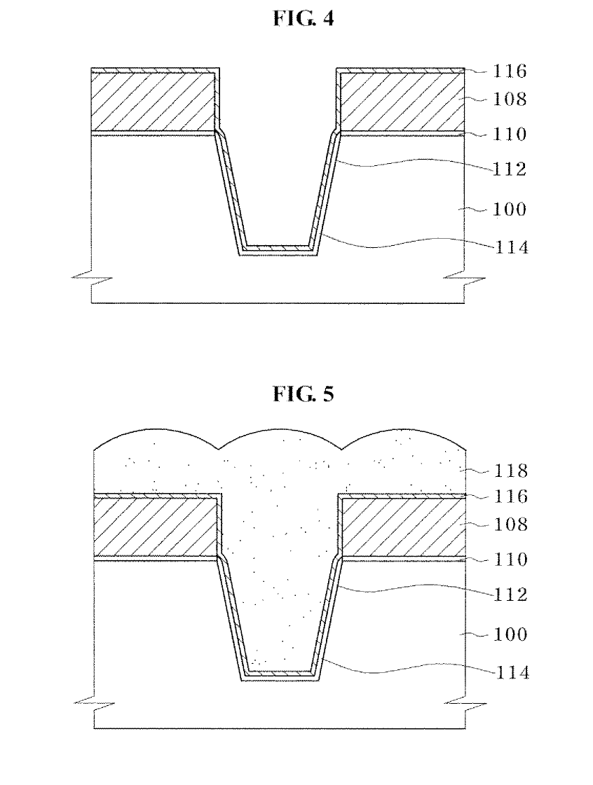

Referring to FIG. 4, the exposed region of the semiconductor substrate 100 is etched to a predetermined depth using the pad nitride layer pattern 108 and the pad oxide layer pattern 110 as mask layers, thereby forming a trench 112 inside the semiconductor substrate 100.

Subsequently, the semiconductor substrate 100 is oxidized to form a sidewall oxide layer 114 over the surface of the exposed region of the trench 112. The formation of the sidewall oxide layer 114 is carried out by thermal oxidation (e g., dry oxidation). Then, a liner nitride layer 116 is formed over the sidewall oxide layer 114. The sidewall oxide layer 114 repairs damage to the semiconductor substrate 100 caused by the etching used t form the trench 112. The liner nitride layer 116 serves as an etching barrier layer when forming a spacer layer arranged in the trench and as a passivation layer to protect the semiconductor substrate 100 upon the subsequent formation of an insulating layer used to fill the trench.

Referring to FIG. 5, a fluid insulating layer 118 is formed semiconductor substrate 100. The fluid insulating layer 118 is formed by using a coating apparatus to apply a flowable liquid material onto the semiconductor substrate 100. The fluid insulating layer 113 is a highly reflowable material, such as a spin-on dielectric (SOD) or a polysilazane-containing material. The use of the liquid material in the application enables a narrow trench to be completely filled without voids.

To use the fluid insulating layer 118 as an insulating layer for filling the trench, the flowable liquid material is applied to the semiconductor substrate 100 using the coating apparatus, and the coating is cure in curing equipment at a desired temperature to convert the fluid insulating layer 118 into a silicon oxide (SiO₂) layer. During the curing, chemical reactions between compounds having Si—N—H bonds convert the fluid insulating layer 118 into the silicon oxide (SiO₂) layer. During the curing, the fluid insulating layer 113 is densified by the removal of impurities present therein. Curing conditions greatly affect the physical properties of the silicon dioxide (SiO₂) layer and the subsequent etching characteristics. Accordingly, there is a need for curing conditions capable of forming a more stable oxide layer,

The curing is generally carried out by steam annealing at 900° C. or higher or by generating steam with a catalyst. The curing results vary depending upon the time delay. Accordingly to stabilize the etching, the following process is performed after time delay of about 8 hours. The time delay causes a long production time and a low production efficiency. A difference in etching rate between lots occurs, thus making it difficult to secure stability of the device. FIG. 8 illustrates the variation in the etching rate as a function the time delay. Referring to FIG. 8, the etching rate is reduced with the passage of the time. Accordingly, one embodiment of the invention suggests a curing method capable of densifying the fluid insulating layer 113 while minimizing the time delay.

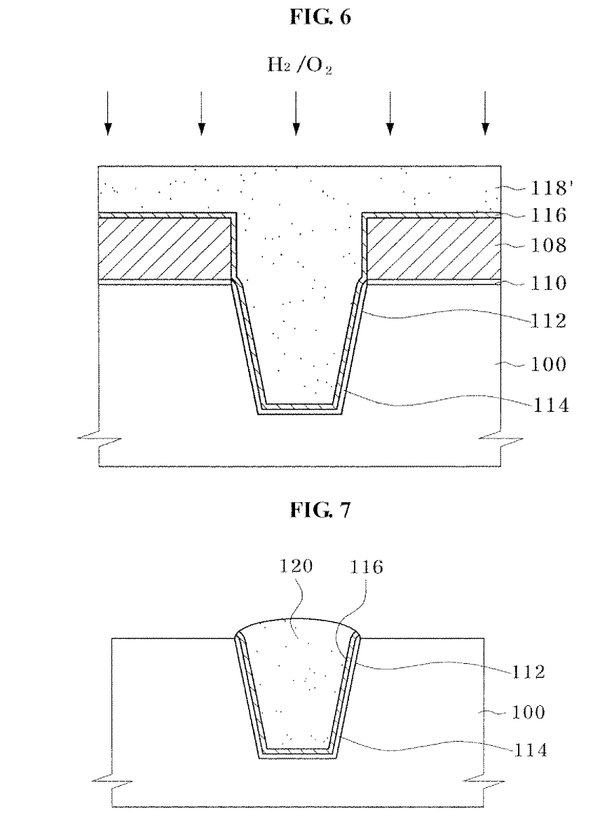

Referring to FIG. 6, the fluid insulating layer 118′ is densified by curing the semiconductor substrate 100 with plasma oxidation. The surface of the fluid insulating layer 118′ is considerably planarized via the densification.

The curing of the fluid insulating layer 118′ is preferably carried out by annealing using wet Oxidation at a low temperature. The wet oxidation serves to outgas contaminants disadvantageously affecting a subsequently formed insulating layer. In addition, the wet oxidation effectively enables the porous structure inside the fluid insulating layer 118′ to be denser.

Hereinafter, the curing will be described in more detail.

First, the semiconductor substrate 100, where the fluid insulating layer 118′ is formed, is loaded into a curing system Then, a predetermined power is applied to the curing system while the plasma source (e.g., argon (Ar) gas), is introduced into the system, thereby forming plasma therein An oxidation source (e.g., oxygen (O₂) and/or hydrogen (H₂) gas), serving as a catalyst to facilitate the oxidation of the fluid insulating layer 118′, is introduced into the system. The curing is preferably carried out at a temperature of 250° C. to 350° C. and a pressure of 0.1 Torr to 1 Torr. When the power is applied to generate plasma in the curing system, a high-frequency wave, (e.g., a microwave having a frequency of 2 GHz to 2.5 GHz, for example 2.45 GHz), is preferably used to minimize the depth of plasma generated inside the semiconductor substrate 100, (i.e., the plasma generation depth), and to minimize damage to the semiconductor substrate 100 caused by plasma.

The curing is preferably carried out by remote plasma generation in a furnace to minimize the influence of the plasma Upon introducing the oxidation source as the catalyst to facilitate the oxidation of the fluid insulating layer 118′, the amount of the gas introduced may be varied to obtain an oxygen-rich or hydrogen-rich atmosphere. In the exemplary embodiments of the invention, the curing is carried out in an oxygen-rich atmosphere. In the oxygen-rich atmosphere, the amount of hydrogen (H₂) is 40% or less of that of oxygen (O₂).

The oxidation catalyst for the fluid insulating layer 118′ induces combustion (i.e., a so-called, “flame reaction”) and generation of steam (H₂O) even when using hydrogen or oxygen in a small amount. Furthermore, the catalyst induces a flame reaction at pressures ranging from 1 Torr to 700 Torr, thus enabling control of a considerably thin oxidation layer. In a case that the fluid insulating layer 118′ is cured under these conditions, the structural transformation (i.e., decomposition of the Si—N—H bonds and generation of silicon dioxide (SiO₂)) of the fluid insulating layer 118′ is effected. The use of plasma oxidation allows the steam (H₂O) to permeate to the inside of the trench, thus permitting efficient conversion of the entire fluid insulating layer 118′ into the silicon oxide layer. In addition, the conversion of the fluid insulating layer 118′ into the silicon oxide layer using plasma oxidation minimizes the variation in etching rate depending upon time delay.

Referring to FIG. 7, the fluid insulating layer 118′ is planarized to form a trench isolation layer 120. The formation of the trench isolation layer 120 is carried out by chemical mechanical polishing (CMP) or an etch-back process.

The trench isolation layer 120 of the invention is densified by curing the fluid insulating layer 118′ with plasma oxidation. The plasma oxidation-induced curing exhibits superior reactivity and enables control of a considerably thin oxidation layer, as compared to conventional curing methods. As a result, a reduction in etching rate resulting form a time delay can be prevented. The stability of the device can be improved due to a prolonged process time. In addition, plasma oxidation ensures that the curing reaction takes places in the internal region of a narrow trench, thus permitting a uniform etching rate of the isolation layer.

As apparent from the foregoing, according to the method for forming a trench isolation layer in a semiconductor device, a fluid insulating layer is cured using plasma oxidation. As a result, a considerably thin oxidation layer can be controlled via an improvement in reactivity. The reduction in etching as a function of time delay rate can he prevented. In addition, plasma oxidation ensures densification of the internal region of a narrow trench, thus forming uniform isolation layer.

Although preferred embodiments of the invention have been disclosed for illustrative purposes, those skilled in the art will appreciate that various modifications, additions and substitutions are possible, without departing from the scope and spirit of the invention as defined in the accompanying claims.

What is claimed is:

1. A method for forming an isolation layer in a semiconductor device comprising:
forming a trench in a semiconductor substrate;
forming a fluid insulating layer over the semiconductor substrate, thereby filling the trench with the fluid insulating layer;
curing the semiconductor substrate by plasma oxidation to density the fluid insulating layer; and
planarizing the fluid insulating layer to form an isolation layer.

2. The method according to claim 11 further comprising:
after forming the trench,
forming a sidewall oxide layer over the exposed region of the trench; and
forming a liner nitride layer over the sidewall oxide layer.

3. The method according to claim 1 wherein the fluid insulating layer comprises spin-on dielectric (SOD) material or polysilazane.

4. The method according to claim 1, wherein the step of curing comprises:
loading the semiconductor substrate into a curing system;
introducing argon (Ar) gas into the curing system to generate plasma in the curing system; and
densifying the fluid insulating layer by introducing an oxidation source into the curing system, the oxidation source comprising oxygen (O₂) gas, hydrogen (H₂) gas, or mixtures thereof

5. The method according to claim 1, comprising performing the plasma oxidation at a temperature of 250° C. to 350° C. and a pressure of 0.1 Torr to 1 Torr.

6. The method according to claim 1, comprising performing the curing in a furnace.

7. The method according to claim 1, comprising performing the curing using microwaves at a frequency of 2 GHz to 2.5 GHz.

8. The method according to claim 4, wherein the oxidation source comprises hydrogen (H) gas and oxygen (O₂) gas, the hydrogen (H₂) gas being used in an amount of 40% or less relative to the amount of oxygen (O₂) gas.

9. The method according to claim 4, comprising generating plasma by remote plasma generation.
